(19) United States
(12) Patent Application Publication
(10) Pub. No.: US 2017/0324394 A1
(43) Pub. Date: Nov. 9, 2017

(54) SAW TRANSDUCER WITH SUPPRESSED MODE CONVERSION

(71) Applicant: SNAPTRACK, INC., San Diego, CA (US)

(72) Inventors: Thomas EBNER, München (DE); Markus MAYER, Taufkirchen (DE); Ulrike RÖSLER, Hebertshausen (DE); Gholamreza DADGAR JAVID, München (DE); Stefan BEREK, München (DE)

(21) Appl. No.: 15/531,325

(22) PCT Filed: Dec. 2, 2015
(86) PCT No.: PCT/EP2015/078421

§ 371 Date: May 26, 2017

(30) Foreign Application Priority Data
Dec. 17, 2014 (DE) 10 2014 118 897.7

(51) Int. Cl. H03H 9/02; H03H 9/25

(52) U.S. Cl. CPC H03H 9/02818; H03H 9/25; H03H 9/02559; H03H 9/02992

(57) ABSTRACT

A transducer for SAW-type or PSAW-type acoustic waves is proposed in which the dielectric (DK) is applied onto the substrate so that the gap (GP) between the ends of the electrode fingers and the opposite bus electrode is completely filled with said dielectric (DK), but the active area of the transducer, thus transversal overlap area (UB) of the electrode fingers, is not covered by said dielectric.

SAW (Surface Acoustic Wave)-type acoustic waves are generated by means of electroacoustic transducers on piezoelectric substrates, and especially monocrystalline piezoelectric substrates. Depending on the substrate used, and given crystalline substrates, different modes of the acoustic wave may be preferred depending on the crystal cut. These may differ in wave number, and especially in the propagation velocity of the acoustic wave. Since these two variables affect the frequency of the acoustic wave, it is necessary to suppress or to attenuate modes occurring at interfering frequencies in order to ensure a signal transmission that is unaffected by signals of interfering modes. Primarily those modes that generate signals in a stop band near the fundamental or resonance frequency, or even within the passband of a filter operating with SAWs, are interfering.

Furthermore, given SAW filters that are constructed on lithium tantalate substrates, radiation losses arise that increase strongly as the aperture becomes smaller. A loss mechanism exists that reduces the energy of the wave or the mode to be used. These losses lead to a corresponding increase in the insertion attenuation that is not acceptable for application in the mobile communications field.

Previously, practically no possibilities to suppress these radiation losses had been found given SAW filters on lithium tantalate substrates. The single possibility to keep these losses as small as possible exists in selecting a sufficiently large aperture for the SAW filter. Such a limit value with still acceptable losses exists given an aperture in the range of 20λ, thus 20 times the length of the acoustic wave. The losses may additionally be minimized if the gaps—thus the spacing of the finger ends from the respective adjacent bus electrode, or from the transversally adjacent stub finger—are kept as small as possible. It is also helpful to set the length of the stub finger to a value >1.5λ.

Even given SAW elements on lithium niobate substrates, radiation losses may occur. In order to reduce these, various possibilities have been proposed to improve the quality of the acoustic waveguide so that an ideal piston mode appears. For this, the geometry of the acoustic trace is designed so that a specific transversal velocity profile is created that, at the border, is characterized by a narrow area with reduced velocity. This is preferably chosen within the transversal area. The goal is to suppress unwanted transversal modes, or to not allow them to be created.

From US 2014/0001919 A1, a transducer for elastic waves is known in which the velocity of the acoustic wave is set to be higher in the overlap area than in the non-overlap area. For this, the transducer is coated with a dielectric in the gap area.

From WO 2011/088904 A1, measures are known to adjust the transversal velocity profile in a transducer.

From U.S. Pat. No. 7,576,471 B1, it is also known to adjust the acoustic velocity to be lower in a border area comprising one of the finger ends, the gap area and the busbars than in the central overlap area.

However, corresponding transducer geometries on lithium tantalate substrates are not reduced to the desired degree.

It is therefore an object of the present invention to specify a SAW transducer that may reduce the radiation losses in SAW elements, and especially in SAW filters on lithium tantalate substrates.

This objective is achieved according to the invention by a transducer having the features of claim 1. Advantageous embodiments of the invention are provided in additional claims.

A transducer is specified for SAW (Surface Acoustic Wave)-type or PSAW (Pseudo-Surface Acoustic Wave)-type acoustic waves. This is assembled on a substrate made up of a leaky-wave substrate, and especially of lithium tantalate, which exhibits a crystal cut beneficial to the generation of SAW. Arranged on the substrate are two electrode combs that respectively have a bus electrode and electrode fingers connected therewith. The two electrode combs are interleaved so that the electrode fingers mutually, interdigitally overlap in a transversal overlap area of the transducer.

A gap is formed between the ends of overlapping electrode fingers and the bus electrode of the opposite electrode comb, meaning that a free clearance remains between the two electrically conductive structures. Alternatively, the gap may also be formed between the finger ends of two opposing electrode fingers, of which the longer is an overlapping electrode finger and the shorter is a stub finger, thus a non-overlapping electrode finger.

According to the invention, a dielectric is now applied onto the substrate so that the gap is completely filled with this, but the transversal overlap area
in which the electrode fingers of opposite comb electrodes overlap
is not covered by the dielectric and therefore is free of dielectric.

With regard to material and layer thickness, the dielectric is chosen so that an acoustic wave experiences approximately the same acoustic impedance in the transversal overlap area and in the gap area, and the acoustic wave therefore travels just as quickly in the gap area as within the overlap area.

The inventors have recognized that a mode conversion from the desired mode into an unwanted mode occurs at the gap in SAW transducers. The preferably used mode is a polarized shear wave, leaky wave or also a leaky surface wave. From this, a Rayleigh wave or a volume wave typically arises in the gap area due to mode conversion. Mode conversion is especially created due to scattering of acoustic waves of the desired mode in the gap area. In known transducers, the unwanted mode is thus not generated in the gap area; rather, the mode that is to be used that is generated in the acoustic trace is converted in the gap area into an unwanted mode having different properties, and especially having a different frequency position.

With the aid of the dielectric (which, according to the invention, completely fills the gap but is not arranged in the overlap area), a structure is achieved that provides a uniform acoustic impedance to the acoustic wave, or the desired fundamental mode, over the entire width of the acoustic trace. A dielectric is preferably used which has an acoustic impedance that comes as close as possible to that of the electrode material that is used.

In a transducer having such a dielectric and having optimally adapted acoustic impedance, the acoustic wave also travels just as quickly in the gap area as within the acoustic trace, or as within the overlap area. At the boundary of the overlap area, at the transition into the gap area, the transducer according to the invention no longer exhibits any discontinuities with regard to acoustic impedance and/or the phase velocity. In this way it is achieved to nearly completely suppress the mode conversion in the gap area of the transducer according to the invention.

According to one embodiment, the dielectric is applied onto the piezoelectric substrate in the form of two parallel strips. The strips respectively travel parallel to the lengthwise direction, which is also designated as a longitudinal direction. Each of the strips thereby completely covers a gap area of the transducer but leaves the transversal overlap area uncovered. Two strips of dielectric are required since the transducer has two gap areas that are arranged to both sides of the transversal overlap area. A dielectric applied in strip form can be applied especially simply and be structured uniformly in the longitudinal direction, such that no additional discontinuities are thereby generated.

The dielectric may be applied directly onto the substrate before the metallization for the electrode combs is generated. However, it is advantageous to apply the dielectric only after the generation of the electrode structure. In this way, it is ensured that the electrode layer rests flush on the substrate and itself exhibits no discontinuities that would otherwise be worrisome, at least in the border area toward the dielectric.

The strips of the dielectric that travel in the longitudinal direction at least cover the gap; however, in one embodiment they may also spread such that, beyond the gap area, they also additionally cover the directly adjacent border area of the transducer. Although the border area exhibits no discontinuities relative to the overlap area, it is technically advantageous, and advantageous with regard to the manufacturing process of the dielectric, to spread the dielectric strips in the direction pointing away from the overlap area. The same finger pattern as in the overlap area is provided in the border area; however, no overlapping occurs there since stub fingers and overlapping fingers are connected with the same bus electrode in the border area, and thus have the same potential.

The dielectric covers at least the gap area. According to one embodiment, the dielectric is structured in the form of individual dots that precisely fill the gap. Each dot extends transversally, precisely and exclusively over the gap area. In the longitudinal direction, it may have the same width as or a width at least similar to that of the electrode fingers.

In this embodiment, the typically metallic electrode finger with the same or similar cross section profile is extended by the dielectric or by the dots of the dielectric in the direction of the opposite bus electrode.

With such an embodiment, an especially uniform acoustic impedance distribution is achieved in the transversal direction between the two bus electrodes. However, a disadvantage of this embodiment is that the dots are more complicated to structure, and the structuring process is to be adapted to the electrode structure.

It is the optimization goal of the transducer according to the invention to design the acoustic impedance to be as uniform as possible in the transversal direction. This is achieved in the area of the dielectric in that it is selected, in terms of material and layer thickness, so that the correct impedance appears, meaning that it exhibits the same or a similar impedance as the in the overlap area. Since the acoustic impedance results as a product of the density of a structure applied on the surface and the velocity of the acoustic wave, the acoustic wave may be adjusted both via the density and the phase velocity. The density is purely a material value that is determined via the type or modification of the dielectric and is less variable. In contrast to this, the velocity of the acoustic wave may especially be influenced by the surface coverage, such that the layer thickness of the dielectric in the gap area may be varied as an adjustable parameter.

A preferred electrode material for the transducer, thus for the metallization at the electrode fingers, comprises aluminum which may additionally comprise copper contents or partial copper layers, as well as titanium. The metallization then preferably has a multi-layer structure whose individual layers comprise the aforementioned metals in pure form or in the form of alloys. The acoustic impedance then integrally results over the entire layer structure of the electrode fingers. In a transducer that has an electrode structure having such a layer design, SiO₂ or silicon nitride as a dielectric is preferably selected as a sole or primary component. The height of the dielectric may then be set to a value that corresponds to 10 to 500% of the height of the metallization. For a dielectric applied in a strip shape which extends in a longitudinal direction, a smaller layer thickness of the dielectric that is typically chosen in the size range of the metal layer thickness is more preferred.

For a dielectric applied in the gap area in the form of individual dots, a greater layer thickness is more preferred. For a transducer that has a metallization as indicated above or multi-layer structure as indicated above, SiO₂ is especially preferred as a dielectric and is then applied in a layer thickness of preferably 50 to 150% of the height of the metallization.

As mentioned above, the substrate is selected so that it benefits the generation and propagation of an acoustic wave with the desired mode. If the favored or desired mode is a leaky surface wave, lithium tantalate having a crystal cut LT WI rotYX is chosen as a substrate material, for example. WI thereby indicates the cut angle of the crystal cut. A cut angle in the cut angle range from 39°≦WI≦46° is preferably chosen. The cut angle is especially advantageously 39°, 42° or 46°. However, the invention is also suitable for other leaky wave substrates.

With a transducer according to the invention, SAW elements may be realized that also exhibit less radiation losses given small apertures and larger gaps than elements with known transducers. Such elements then exhibit an improved resonance quality of the individual resonators. Given surface wave elements that comprise resonators, the quality in the range of the resonance of the resonators is improved, especially if smaller apertures are chosen.

The invention will be explained in greater detail below in reference to exemplary embodiments and the accompanying figures. The Figures serves solely for illustration of the invention, and therefore are schematic and not executed true to scale.

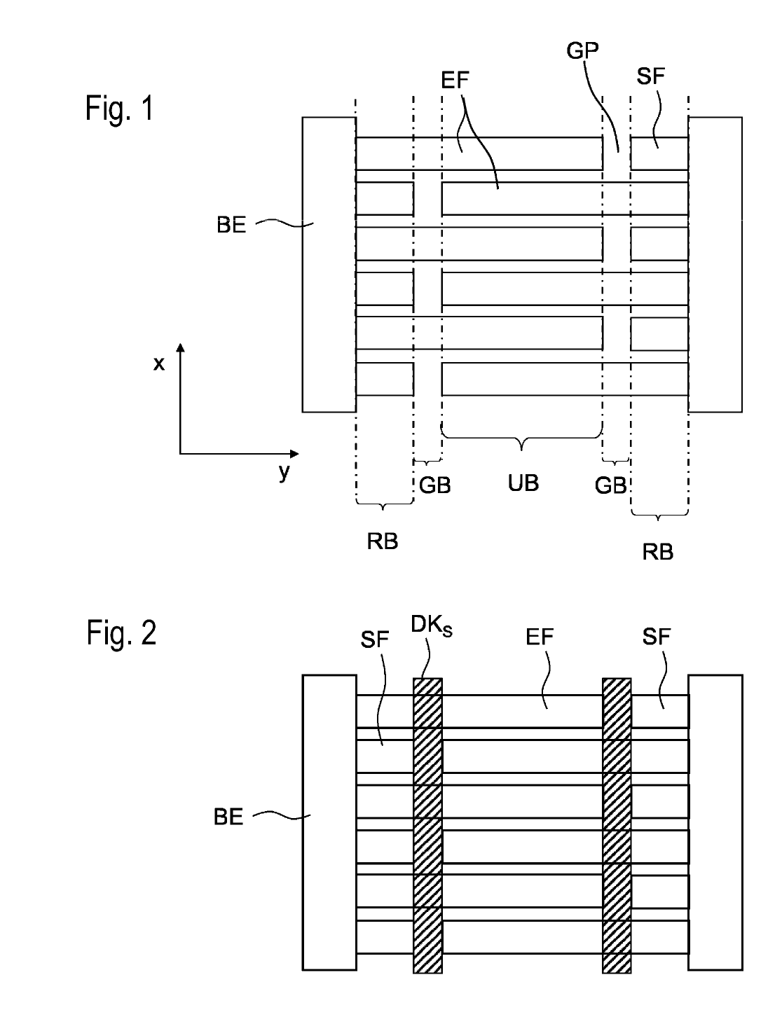

FIG. 1 shows, in schematic plan view, a transducer known per se and its distribution in the overlap area, gap areas and border areas,

FIG. 2 shows, in a schematic plan view, a strip-shaped dielectric applied in the gap area,

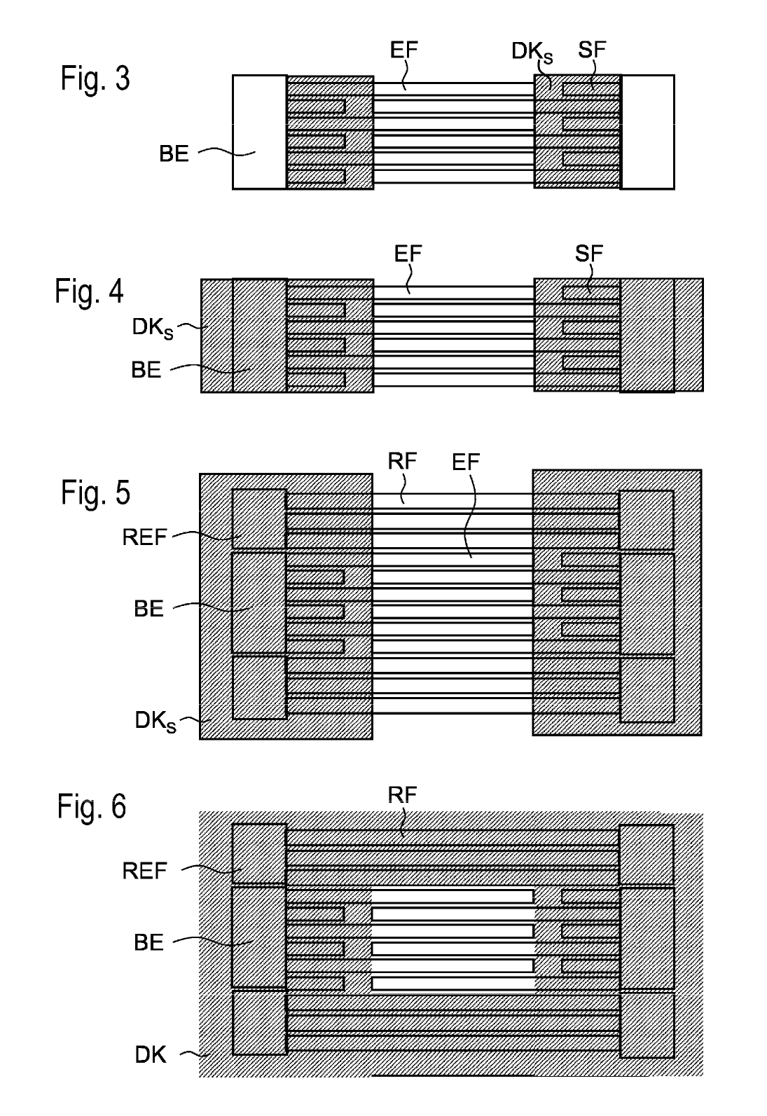

FIG. 3 shows, in the same plan view, as strip-shaped dielectric which also covers the border area,

FIG. 4 shows an applied strip-shaped dielectric which widens again, which dielectric also covers the bus electrode and the directly adjoining area,

FIG. 5 shows a strip-shaped dielectric which covers the gap area, the border area and the bus electrode of a resonator,

Similar to FIG. 5, FIG. 6 shows a resonator in which the dielectric moreover covers the entire reflector of the resonator,

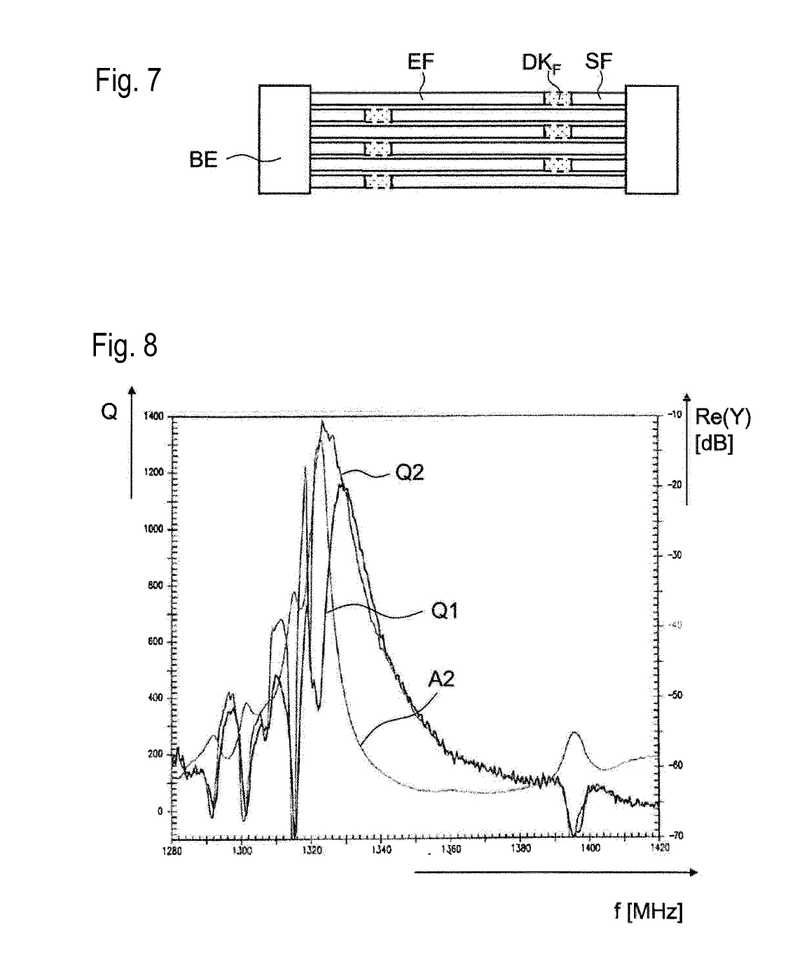

FIG. 7 shows a transducer in plan view in which the dielectric is applied as dots, exclusively in the gap,

FIG. 8 shows the admittance and the quality of a resonator having a transducer according to the invention in comparison to conventional resonators,

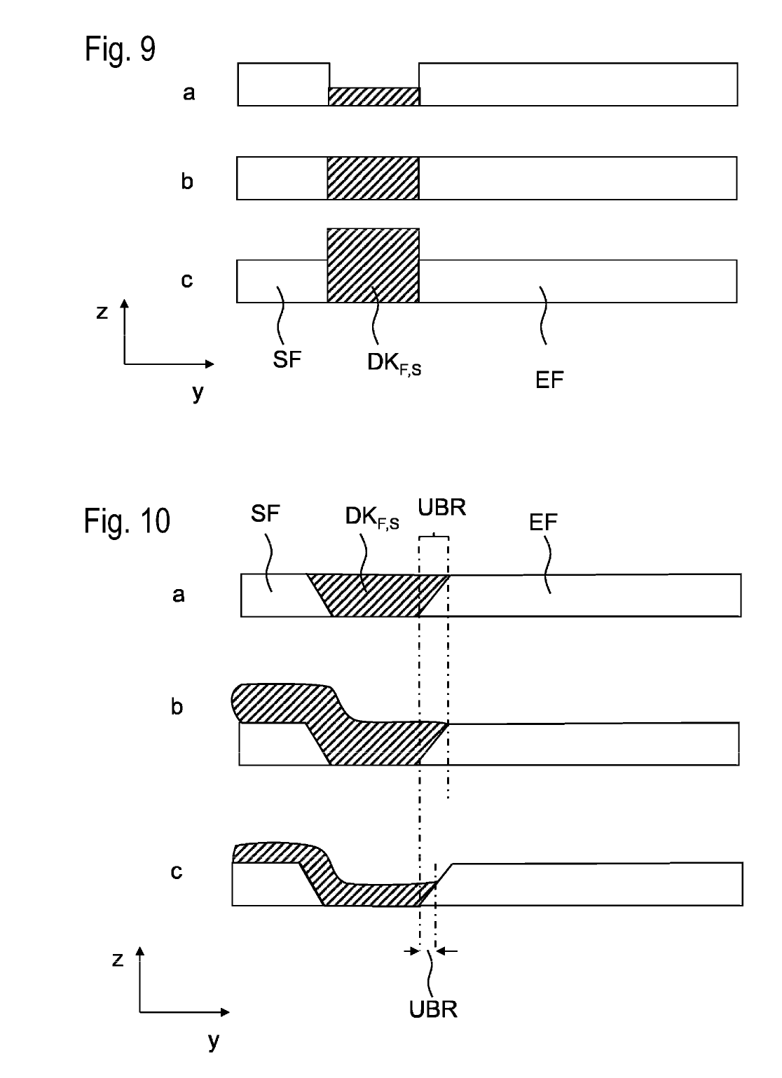

FIG. 9 shows a section in the transversal direction through an electrode finger and the dielectric,

FIG. 10 shows three different sections in the transversal direction through an electrode finger whose metallization at the finger end has an edge that falls away in a non-vertical direction,

FIG. 11 shows dielectrics applied in dot form with different widths, in plan view,

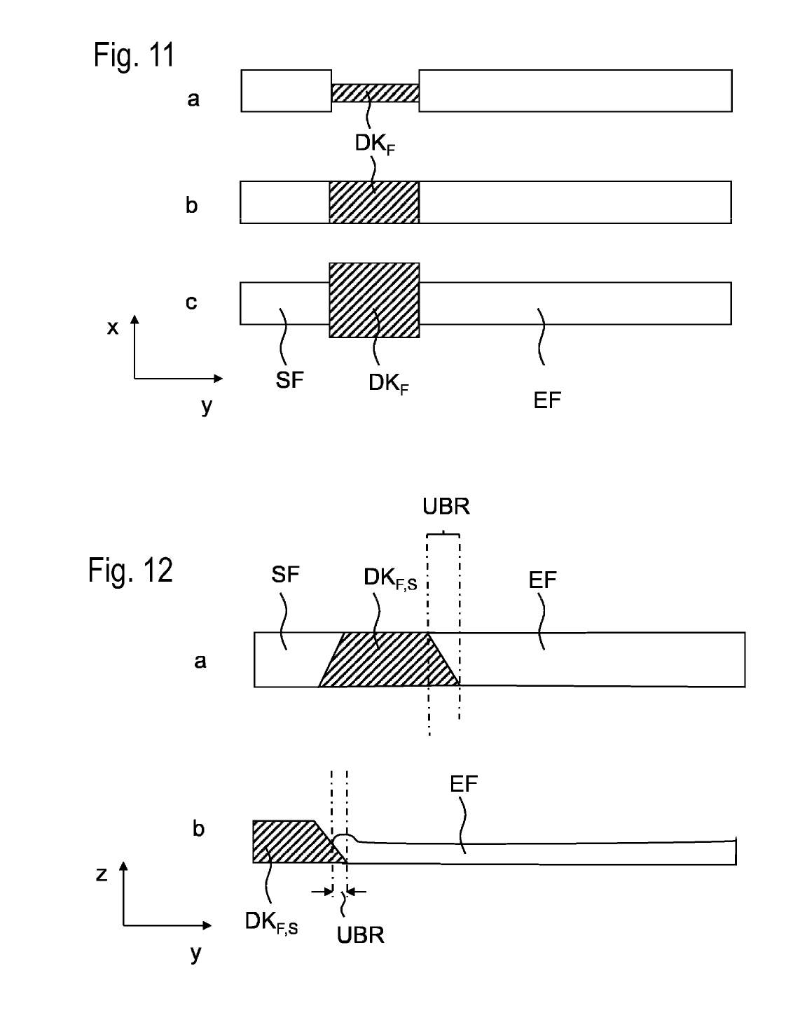

FIG. 12 shows two different sections in the transversal direction through electrode fingers whose metallization at the finger ends has an edge that falls away with negative edge angle in a non-vertical direction.

FIG. 1 shows a transducer known per se in schematic plan view. The transducer comprises at least two bus electrodes BE from which respective electrode fingers EF extend in the transversal direction. The two bus electrodes with the electrode fingers attached thereon respectively form an electrode comb. In the transducer, two electrode combs are interleaved interdigitally so that their electrode fingers overlap in an overlap area UB. A gap GP, consequently a clearance between the two electrodes, is formed in the transversal direction between the ends of the electrode fingers and the bus electrode or the adjacent electrode comb. Another stub finger SF which has no overlap with the respective other electrode comb may be arranged between the gap GP and the nearest bus electrode BE. As shown in FIG. 1, the gap is then formed between the ends of the electrode fingers and the ends of the opposite stub fingers arranged at the same longitudinal position. The entire transducer is then subdivided into the bus electrode BE, the non-overlapping edge area RB, the gap area GB, and the overlap area UB. The gap area GB is then a rectangular area if all gaps are located at the same height transversally and have approximately the same transversal width. The drawn coordinate system shows that the transversal direction corresponds to the y-axis and that the longitudinal direction in the propagation direction of the acoustic surface wave corresponds to the x-axis.

FIG. 2 shows a first embodiment of the invention in which a respective strip of a dielectric precisely covers one of the two gap areas GB of the transducer. The overlap area is not covered by the dielectric. The border of the strip-shaped dielectric that faces toward the overlap area terminates flush with the finger end of the overlapping finger. The edge of the strip-shaped dielectric that faces toward the bus electrode BE here likewise terminates flush with the ends of the stub fingers; however, this may also partially overlap. It is thereby clear that a flush termination of finger ends and strip-shaped dielectric is thereby only achieved when at least the electrode fingers have steeply falling edges, in the ideal case even vertically falling edges. This is not achieved in practice with real structuring processes.

FIG. 3 shows a transducer according to the invention in plan view, in which the strip-shaped, structured dielectric DK also completely covers the border area of the transducer in addition to the gap area. Therefore, the entire transducer area is covered by the dielectric, with the exception of the bus electrode BE and the overlap area UB.

FIG. 4 shows in plan view a dielectric applied in strip shape, which dielectric additionally covers the bus electrode BE in addition to the gap area GB and border area RB, and optionally also additionally covers an adjoining area outside of the acoustic trace or outside of the transducer.

FIG. 5 shows a transducer that is part of an acoustic resonator. Given a resonator, acoustic reflectors are arranged in the longitudinal direction on both sides of the acoustic transducer. These comprise strip-shaped reflectors that exhibit finger width and finger spacing similar to the electrode fingers in the overlap area. The reflector is electrically insulated from the transducer, or is connected with only one of the potentials, preferably to ground. Given this embodiment in the resonator, the dielectric applied in strip form also additionally extends in the longitudinal direction across both reflectors. The transversal extent of the strip-shaped dielectric may vary as shown in FIGS. 2 through 4.

FIG. 6 shows a further embodiment having a resonator in schematic plan view, in which the entire resonator or resonators are also covered by the dielectric in addition to the surfaces shown in FIG. 5. Within the resonator, only the overlap area thereby remains uncovered, and there only the overlapping electrode fingers of the dielectric.

FIG. 7 shows an embodiment of a transducer in which the dielectric is structured in the form of dots and is arranged exclusively in the gaps. The dots are located in the gap area between finger ends of overlapping fingers and stub fingers, but not on the electrode fingers EF in the gap area. The width of the dots may vary, but approximately corresponds to the width of the electrode finger.

FIG. 8 shows three curves Q1, Q2 and A2, wherein Q1 shows the quality of a conventional resonator and Q2 shows the quality of a resonator according to the invention, coated with dielectric in the gap area, whereas A2 reflects the real part of the admittance of a transducer according to the invention. From the ratio of the two curves Q1 and Q2, it is clear that the quality of a transducer according to the invention, coated with dielectric in the gap area, significantly surpasses the quality of the conventional resonator. According to the presented example, at its peak the quality here is increased from 1160 to 1380, for example.

FIG. 9 shows three cross sections a through c in the transversal direction through electrode fingers, dielectric DK and stub finger SF. The z-axis shown in the Figure is the normal relative to the surface of the piezoelectric substrate. The three sections differ in the height of the applied dielectric DK. Whereas the layer thickness of the dielectric DK is smaller than the metallization height of the electrode finger EF in FIG. 9A, in FIG. 9B it approximately corresponds to the metallization height. In FIG. 9C, the dielectric DK has a significantly greater layer thickness than the metallization of the electrode finger EF.

FIG. 10 likewise shows three different cross sections through electrode finger EF, dielectric DK and stub finger SF. In this depiction, the cross section profiles of the electrode fingers is depicted closer to reality, meaning that the cross section profile of the electrode fingers does not fall away vertically relative to the substrate at the end of the finger but rather is rounded or beveled.

In the cross section depiction of FIG. 10A, the dielectric DK_{S, F} fills the gap so that the edge profile of the DK_{S, F} corresponds to the inverse of the edge profile at the ends of the electrode fingers EF. In plan view, a blurry region UBR results in which the diagonally trailing edges of electrode fingers EF and dielectric DK_{S, F} overlap, such that in plan view no clear separation is to be drawn between dielectric and electrode fingers. In the instances in which a blurry region UBR exists, by definition both gap area and overlap area UB end “indistinctly” within the blurry region BR since the boundaries are effectively blurred across the blurry area UBR.

FIG. 10B shows an electrode finger likewise having diagonally trailing edge profile of the electrode fingers and a dielectric which is applied in the gap area and additionally covers the border area. The edge of the dielectric that faces toward the overlap area UB falls away with the same slope as the metallization at the end of the electrode finger, such that here as well a blurry region UBR is formed at the boundary between dielectric and electrode finger. The dielectric now extends across the upper edge of the electrode finger end, thus ends in a blurry region UBR.

FIG. 10C likewise shows a dielectric DK applied overlapping the electrode finger or electrode fingers EF in the blurry area UBR, with smaller layer thickness than the metallization of the electrode finger.

FIG. 11 shows in plan view three exemplary embodiments of dielectric DK applied in the form of dots. In FIG. 11A, the dielectric DK_{F} is introduced into the gap with smaller width than the electrode fingers EF. In FIG. 11B, the outer edges of the dielectric DKF align with the outer edges of the electrode finger EF, whereas in FIG. 11C the dielectric DK_{F} has a greater longitudinal width than the electrode fingers EF.

In FIG. 10A, with dielectric applied in dots or dielectric applied in the form of strips exclusively in the gap area, the boundary area between gap area GB and overlap area UB is a blurry area UBR in which the profiles of dielectric and metallization intersect. The blurry area UBR here is limited to a maximum transversal length of respectively 1 μm. In the exemplary embodiments according to FIGS. 10B and C, if the dielectric DK additionally extends beyond the border area, the bus electrode and the adjoining area outside of the transducer, the intersection of the dielectric with the overlap area UB is up to a maximum of 2 μm.

Given a DK_{F} structured in the form of dots, as shown in plan view in FIG. 11, there may be a tradeoff between the maximum width of the blurry area UBR of the dielectric DK_{F} with the edge of the electrode finger trailing off at the finger end and the longitudinal width of the dielectric dot DK_{F}. A dot that is wider in the longitudinal direction may have a smaller blurry area UBR; by contrast to this, a narrower dot may have a larger blurry area UBR at the boundary with the overlap area UB.

Shown in FIG. 12, using schematic transversal sections directed through each electrode finger EF, is the embodiment in which the dielectric DK is applied chronologically before the metallization for the electrode fingers and the bus electrodes BE. Depending on manufacturing, the dielectric DK_{F, S}, which may be applied as dots DK_{F} or as strips DK_{S}, has an edge profile that has a defined slope angle relative to the substrate. The metallization applied in a later step for electrode fingers EF and stub fingers SF adapts to the edge of the dielectric DK, and accordingly has an inverse edge profile matching this. Considered in plan view, here the boundary between gap area GB and overlap area UB can also not be clearly defined since an overlap between dielectric and metallization of the electrode finger EF is present in the blurry area UBR.

According to the invention, the value of this blurry area UBR is now set to a value that corresponds at most to the aforementioned limit values. A strip-shaped dielectric DK_{S} which covers or fills the outer area and the gap area GB may thus cover the overlap area UB up to a blurry area UBR of at most 2 μm. A dielectric DK_{S} which is applied in the form of strips exclusively in the gap area should cover the adjacent ends of stub fingers SF and electrode fingers EF with a blurry area of at most 1 μm each. If the dielectric DK_{F} is applied in dot form exclusively in the gap, the two-sided overlap in the blurry area may thus likewise be set to a maximum of 1 to 2 μm.

The two different embodiments in FIGS. 12A and 12B indicate embodiments having different layer thickness ratios of dielectric DK and metallization for electrode fingers EF. It has been shown that a smaller blurry area EBR may be maintained with a smaller layer thickness of the metallization of the layer thickness of the electrode finger EF given unchanged layer thickness of the dielectric DK and unchanged edge angles. The smaller that the blurry area UBR is chosen to be, the more uniformly that the acoustic impedance of the entire structure may be set.

The invention could be explained only with reference to a few Figures and exemplary embodiments, but is not limited to these. The edge profile of the metallic and dielectric structures may especially deviate from the shown edge profiles depending on technology. Layer thickness ratios and other size ratios may be chosen differently than presented.

In all Figures, for better illustration the ratio of finger width to finger spacing is depicted larger than is typically chosen in transducers. Moreover, the invention is not limited to normal finger transducers in which electrode fingers EF alternately start from different bus electrodes BE in the overlap area UB. It is also possible to modify the connection sequence of the electrode fingers so that two or more different electrode fingers EF arranged in series start from the same bus electrode BE.

Moreover, it is possible to vary the transversal position of the gaps over the length of the transducer so that the gaps do not align in the longitudinal direction. In these instances, it is possible to structure a dielectric applied in a strip shape so that it follows the curve of the gaps. However, in this embodiment it may be especially advantageous to introduce the dielectric into the gaps exclusively in the form of dots. The structuring of the dielectric dots may then exactly follow the position of the respective gaps.

A transducer according to the invention, with dielectric applied in the gap area, is also not limited to the material combinations cited in the exemplary embodiments. For example, if a different conductive metal with deviating acoustic impedance is selected for the metallization, the dielectric is preferably also selected so that its acoustic impedance is adapted to that of the electrode material. For this, it may be necessary to choose a different dielectric than those specified.

### LIST OF REFERENCE SIGNS

BE bus electrode

EF electrode finger

GP gap

SF non-overlapping electrode finger (stub finger)

DK dielectric

UB (transversal) overlap area

DK_{S} strips (of dielectric)

DK_{F} dots (of the dielectric)

GB (transversal) gap area

RB (transversal) border area

REF reflector

RF reflector finger

UBR blurry area

X, y, z spatial directions

1. A transducer for SAW-type or PSAW-type acoustic waves,
constructed on a leaky wave substrate that has a crystal cut benefiting the generation of SAWs
with two electrode combs arranged on the substrate, which electrode combs respectively have electrode fingers (EF) connected with on a bus electrode (BE), wherein the two electrode combs are arranged interleaved with one another so that their electrode fingers (EF) mutually overlap in a transversal overlap area (UB)
in which the ends of overlapping electrode fingers (EF) of a first of the electrode combs and the opposite bus electrode (BE) of the respective second electrode comb, or the respective opposite ends of overlapping and non-overlapping short electrode fingers (SF), are spaced in the transversal direction so that a gap (GP) is formed between them
in which a dielectric (DK) is applied onto the substrate so that the gap (GP) is completely filled with this, but the transversal overlap area (UB) of the electrode fingers is not covered by this
in which the dielectric (DK) is chosen with regard to material and layer thickness so that an acoustic wave experiences approximately the same acoustic impedance in the transversal overlap area (UB) and in the gap area (GB), and the acoustic wave travels just as quickly in the gap area as within the overlap area.

2. The transducer according to claim 1,
in which the dielectric (DK)
is structured in the form of two parallel strips (DK_{S}) that respectively travel parallel to the longitudinal direction of the transducer,
covers the gap area (GB) with the gaps (GP) arranged at the same transversal height, and
leaves the transversal overlap area (UB) uncovered.

3. The transducer according to claim 2,
in which the strips of the dielectric (DKs) are so wide that they moreover extend beyond a border area (RB) of the transducer that comprises the non-overlapping stub fingers (SF), or up to the bus electrode (BE).

4. The transducer according to claim 1,
in which the dielectric (DK_{F}) is structured in the form of individual dots that extend the electrode fingers (EF) with the same or increased width beyond their ends.

5. The transducer according to one of the preceding claims,
in which the dielectric (DK) comprises SiO₂ or silicon nitride
in which the metallization of the electrode fingers (EF) comprises Al, Cu or Ti,
in which the metallization comprises a multi-layer structure made up of the different components in pure form, or in the form of alloys formed with one another
in which the height of the dielectric layer corresponds to 10-500% of the height of the metallization.

6. The transducer according to one of the preceding claims,
in which the dielectric (DK) comprises SiO₂ or is composed of silicon nitride
in which the height of the dielectric layer corresponds to 50-150% of the height of the metallization.

7. The transducer according to one of the preceding claims,
constructed on a substrate that comprises lithium tantalate.

8. The transducer according to claim 7,
in which the lithium tantalate has a crystal cut LT WI rot YX, wherein WI designates the cut angle, and wherein for WI it applies that 39°≦WI≦46, wherein WI is especially selected from 39°, 42° and 46°.

9. The transducer according to one of the preceding claims,
in which the overlap area (UB) has a width of less than 20λ, wherein λ is the wavelength of the acoustic wave, wherein the aperture is preferably between 5λ and less than 20λ.
